(19) United States
(12) Patent Application Publication
(10) Pub. No.: US 2025/0343079 A1
(43) Pub. Date: Nov. 6, 2025

(54) DETERMINING AN ENDPOINT OF A PLANARIZATION PROCESS

(71) Applicant: CHEMPOWER CORPORATION, Beaverton, OR (US)

(72) Inventors: Suryadevara Babu, Portland, OR (US); Sudhanshu Misra, Camas, WA (US)

(21) Appl. No.: 19/200,565

(22) Filed: May 6, 2025

Related U.S. Application Data
(60) Provisional application No. 63/643,287, filed on May 6, 2024.

(51) Int. Cl. H01L 21/66; H01L 21/321

(52) U.S. Cl. CPC H01L 22/26; H01L 21/3212

(57) ABSTRACT

A method for determining an endpoint of a planarization process comprising planarizing a substrate material using a functionalized chemical planarization pad. The functionalized chemical planarization pad includes a plurality of functional groups bonded to a material of the pad. The functional groups are configured, with or without the assistance of reagents in a solution, to chemically react with the substrate material such that a portion of substrate material bonds to the functional groups. One or more parameters of the substrate material and/or the planarization pad are monitored during the planarization process. The endpoint of the planarization process is determined based upon the one or more parameters of the substrate material and/or the planarization pad, and an indication is output that the endpoint is reached.

### BACKGROUND

Chemical mechanical planarization (CMP) is commonly used in integrated circuit fabrication processes to smooth surfaces, such as that of a semiconductor substrate, by removal of material using a combination of chemical and mechanical forces. A typical CMP process involves using an abrasive and/or a chemical slurry that can be corrosive to the material being removed, in combination with a polishing pad. The substrate and polishing pad are pressed together, and rotated relative to one another with non-concentric axes of rotation. The combination of the force and slurry removes areas of the substrate with a higher topology compared to areas with a lower topology, thereby smoothing the surface.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to methods for determining an endpoint of a planarization process. One example provides a method comprising planarizing a substrate material using a functionalized chemical planarization pad. The functionalized chemical planarization pad includes a plurality of functional groups bonded to a material of the pad. The functional groups are configured to enable, independently or in conjunction with reagents present in a solution, removal of the substrate material at least in part by chemically reacting with the substrate material such that a portion of substrate material bonds to the functional groups. One or more parameters of the substrate material and/or the planarization pad are monitored during the planarization process. The endpoint of the planarization process is determined based upon the one or more parameters of the substrate material and/or the planarization pad, and an indication is output that the endpoint is reached.

### BRIEF DESCRIPTION OF THE FIGURES

FIG. 1 shows a block diagram of an example chemical planarization system including an optical monitoring system and a friction monitoring system.

FIG. 2 shows a block diagram of another example chemical planarization system including an optical monitoring system.

FIG. 3A shows a prophetic example of a Fourier-transform infrared (FTIR) spectrum of a functionalized surface of a planarization pad.

FIG. 3B shows another prophetic example of an FTIR of a saturated planarization pad.

FIG. 4 shows a block diagram of an example endpoint determination model in a training phase.

FIG. 5 shows a block diagram of the endpoint determination model of FIG. 4 in a run-time phase.

FIGS. 6A-6B show a flow diagram depicting an example method for determining an endpoint of a planarization process.

FIG. 7 shows a block diagram of an example computing system.

### DETAILED DESCRIPTION

As introduced above, current methods of planarization (e.g., chemical mechanical planarization (CMP)) can be used in a wide variety of device fabrication contexts. During a planarization process, it can be desirable to know when to stop the polishing process to avoid overpolishing and stop the process when an underlying film is reached. However, it can be challenging to determine when an endpoint of the planarization process is reached.

In some instances, the planarization process is performed for a predetermined amount of time. However, this can result in overpolishing of some substrate materials and/or underpolishing of other substrate materials based on natural variation in the thickness of the substrate material.

In other instances, a window can be provided through a polishing pad. The window can be used to view a portion of the polishing pad during the planarization process. However, the window provides visibility through a small portion of the pad, which can result in undersampling. This can lead to overpolishing of other portions of the pad outside the windowed portion.

Accordingly, examples are disclosed herein that relate to methods for determining an endpoint of a planarization process. Briefly, one or more parameters of the substrate material and/or the planarization pad are monitored during the planarization process. The endpoint of the planarization process is determined based upon the one or more parameters of the substrate material and/or the planarization pad, and an indication is output that the endpoint is reached. Using the disclosed methods, the endpoint of the planarization process can be accurately determined based on real-time monitoring. This can help to ensure precise planarization in semiconductor manufacturing processes.

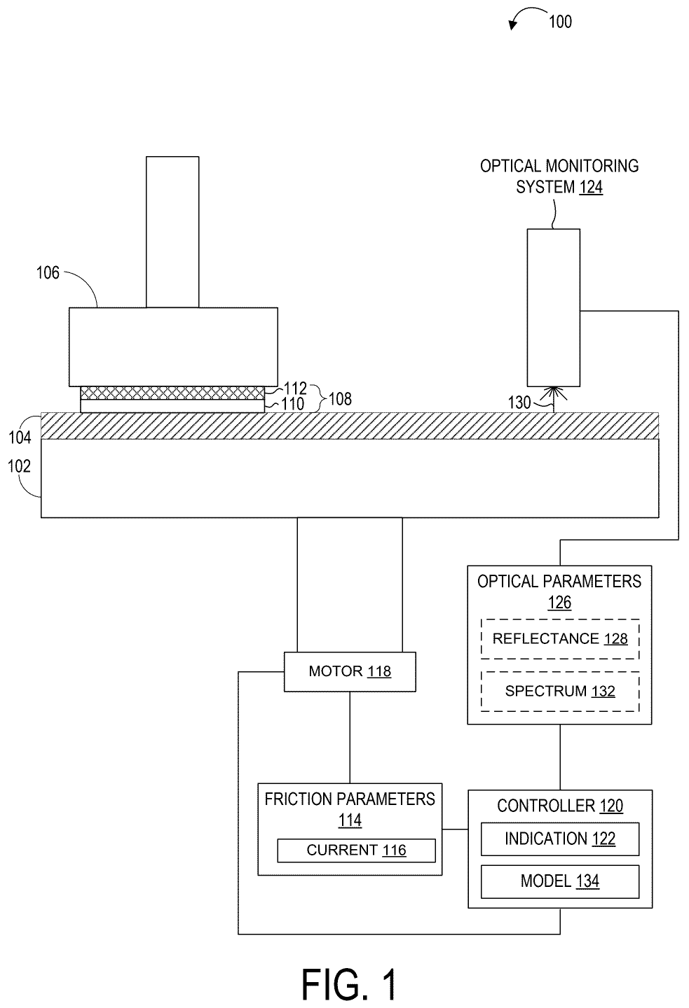

FIG. 1 shows a schematic depiction of an example chemical planarization system 100 that can monitor and determine an endpoint of a planarization process. System 100 comprises a platen 102 that supports a pad 104. The system 100 further includes a substrate holder 106 configured to hold a substrate 108 against the surface of the pad 104. As described in more detail below, the pad 104 comprises a functionalized chemical planarization pad comprising a plurality of functional groups bonded to a material of the pad. The functional groups are configured, independently or in conjunction with reagents present in a solution, to chemically react with a substrate material such that a portion of substrate material bonds to the functional groups to effectuate the planarization of the substrate material. It will be understood that many different configurations and designs are possible for a variety of platform types (e.g., rotary, linear or belt style, vertically, rollers, or hollow fibers).

As described in more detail below, the substrate 108 comprises a first substrate material 110 and a second substrate material 112 underlying the first substrate material 110. Other components (not shown) that may be incorporated into system 100 include, but are not limited to, a planarization solution introduction system for introducing a planarization solution onto the pad, a pad rinsing system configured to rinse possible contaminant materials from the pad (such as complexed materials that have been removed from the surface of the substrate) and/or to clean the pad between using different planarization solution chemistries, a spent solution recovery system, a materials recirculation system (e.g. for recirculating the planarization solution in a closed loop process), and a species stripping system. Additional aspects of the chemical planarization system are described in more detail in U.S. patent application Ser. No. 15/931,556 entitled CHEMICAL PLANARIZATION, filed on May 13, 2020; U.S. patent application Ser. No. 18/149,005 entitled CHEMICAL PLANARIZATION, filed on Dec. 30, 2022; U.S. Provisional Application No. 63/179,995 entitled NOVEL METHODOLOGY FOR REGENERATION AND RECOVERY OF SPECIES IN AN ENHANCED PLANARIZATION PROCESS, filed on Apr. 26, 2021; U.S. patent application Ser. No. 17/729,805 entitled PAD SURFACE REGENERATION AND METAL RECOVERY, filed on Apr. 26, 2022; P.C.T. Application No. PCT/US2022/026364 entitled PAD SURFACE REGENERATION AND METAL RECOVERY, filed on Apr. 26, 2022; U.S. Provisional Application No. 63/240,846 entitled TOOLS FOR CHEMICAL PLANARIZATION, filed on Sep. 3, 2021; U.S. patent application Ser. No. 17/823,857 entitled TOOLS FOR CHEMICAL PLANARIZATION, filed on Aug. 31, 2022; P.C.T. Application No. PCT/US2022/075778 entitled TOOLS FOR CHEMICAL PLANARIZATION, filed on Aug. 31, 2022; U.S. Provisional Application No. 63/504,098 entitled TOOLS FOR CHEMICAL PLANARIZATION, filed on May 24, 2023; and U.S. Provisional Application No. 63/583,818 entitled CHEMICAL PLANARIZATION OF NON-METALLIC MATERIALS, filed on Sep. 19, 2023; the entire contents of which are hereby incorporated by reference for all purposes.

As introduced above, the pad 104 comprises a plurality of functional groups bonded to a material of the pad. In some examples, the functional group comprises a hydrolysis and/or a complexation agent for performing abrasive-free chemical planarization. In some examples, the functional group comprises one or more of a carboxylic acid, an amine, a sulfonic acid, an alcohol, a phosphonic acid, an amide, a sulfate, a nitrate, or a polyethylene. In some more specific examples, the functional group comprises one or more of iminodisuccinic acid, ethlynediaminedisuccnic acid, glutamic acid, methylglycinediacetic acid, dicyanamide, or polydiallyldimethylammonium chloride. Such species can also be used as chelating agents separate from a pad, in addition to or alternatively to the functionalization of a pad with such species. In other examples, any other suitable functionalization may be performed to impart any desired chemical functionality to the pad. Other examples of functional groups include, but are not limited to, —COOCH₂CH₂OH, —N(CH₂CH₂OH)₂, and —CONHR.

In other examples, the pad comprises a distribution of functional groups freely dispersed in a polymer matrix of the pad. In this manner, dispersed species can be released upon contact with a planarization solution to assist in planarization. In yet other examples, the pad comprises a combination of one or more functional groups bonded to a material of the pad and one or more functional groups freely dispersed throughout the pad.

The pad may comprise any suitable material or materials. In some examples, the pad comprises one or more polymer layers. Each polymer layer of the one or more polymer layers can include one or more of polyurethane, polyanhydride, polycarbonate, polyacrylate, polysulfone, polyester, polyacrylonitrile, polyethersulfone, polyarylsulfone, polyacrylonitrile, epoxy, and/or polyvinylidene fluoride.

With reference again to FIG. 1, the system 100 further comprises a monitoring system that can be used to identify an endpoint of the planarization process. As the substrate material is polished, some of the substrate material being removed will bind to the reactive functional groups. This can be used to identify the process endpoint.

In some examples, as binding to the reactive groups increases, a friction coefficient between the pad surface and the film being polished will increase. Accordingly, the endpoint of the planarization process can be determined by monitoring one or more friction parameters 114 between the substrate 108 and the pad 104. In some examples the one or more friction parameters 114 include a drive current 116 for a substrate carrier motor 118. In some examples, when the underlying film is reached, there is a sudden change in the value of the friction coefficient. Since the friction coefficient influences the drive current for the wafer carrier, there will be a similar effect on the drive current, from a gradual increase to a sudden change, signaling the process endpoint. The system 100 further comprises a controller 120 configured to monitor the one or more friction parameters 114. In this manner, the controller 120 can detect the endpoint of the process.

The controller 120 is further configured to output an indication 122 of the endpoint. In some examples, the indication 122 is output to an operator of the processing system 100. In other examples, the indication 122 is additionally or alternatively output to one or more components of the system 100. For example, the controller 120 can be configured to deactivate the motor 118 at an endpoint of the planarization process.

The system 100 additionally or alternatively includes an optical monitoring system 124. The optical monitoring system 124 is configured to monitor one or more optical parameters 126 of the substrate 108 and/or the pad 104. In some examples, monitoring the one or more parameters comprises monitoring reflectance 128 of the planarization pad 104. For example, the optical monitoring system 124 can sense reflection of incident light 130 (e.g., visible light, infrared light, or ultraviolet light) off a surface of the pad 104. Without wishing to be bound by theory, binding of the substrate material to surface groups on the pad can change the reflectance of the pad 104. For example, when polishing a copper substrate material, copper can accumulate on the pad 104, increasing the reflectance of the pad. The reflectance may stop changing when the endpoint is reached. Accordingly, the reflectance of the pad can be correlated to an amount of the substrate material removed from a wafer. In this manner, the reflectance can be used to track the amount of the substrate material removed in real time, and to determine when the endpoint of the polishing process is reached.

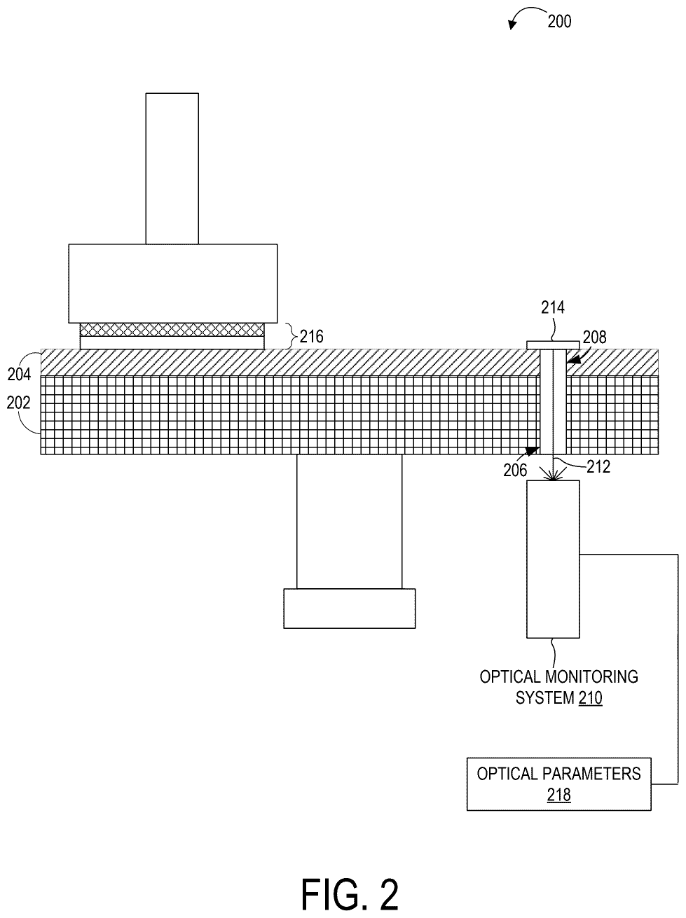

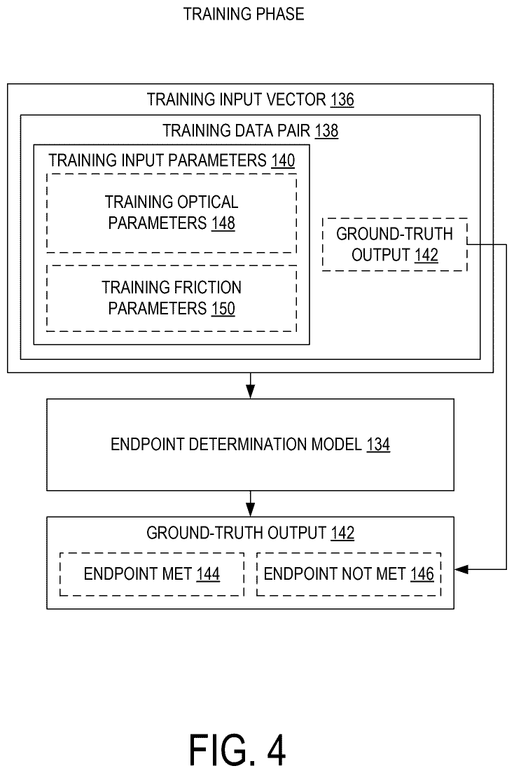

As illustrated in FIG. 1, in some examples, the one or more optical parameters 126 are measured from a substrate-facing surface of the pad 104. In other examples, and with reference to FIG. 4, the one or more optical parameters can be measured from an optical monitoring system placed on an opposite surface of the pad. FIG. 2 shows another example of a chemical planarization system 200 comprising a platen 202 that supports a pad 204. The platen 202 and the pad 204 each comprise a window 206, 208, respectively. The windows 206, 208 are aligned, such that an optical monitoring system 210 can transmit and/or receive light 212 through the platen 202 and the pad 204. In some examples, the window 206 and/or the window 208 comprise an open aperture. In other examples, the window 206 and/or the window 208 can be at least partially filled with a suitable material that is transparent to the light 212. Examples of suitable materials include, but are not limited to, glass, acrylic, and polycarbonate materials.

The system 200 further comprises a mirror 214 placed on a surface of the pad. During a copper polishing process, the pad 204 rotates such that different portions of the pad contact different portions of the substrate 216 over the duration of the polishing process. Some copper will be deposited on the mirror as it transits across a substrate 216, thus changing the reflectance of the mirror. This change in reflectance can be correlated to the amount of copper removed from the substrate.

In the example of FIG. 2, the mirror 214 is placed on top of the aperture 208. In this manner, the optical monitoring system 210 can observe the reflectance of the mirror through the platen 202 and the pad 204. The optical monitoring system 210 accordingly furnishes optical parameters 218 that indicate when an endpoint of the polishing process is reached.

Furthermore, the motion of the pad 204 results in the mirror 214 obtaining a sample that represents an average across a surface of the substrate 216. This can provide a more accurate measurement of the progress of the polishing process than optical endpointing techniques that observe one or more specific locations on the substrate 216 and/or the pad 204.

Referring again to FIG. 1, in some examples, monitoring the one or more parameters comprises monitoring an optical spectrum 132 of the planarization pad 104 to detect appearance of the second substrate material 112 underlying the first substrate material 110. For example, in a copper polishing process, the first substrate material 110 may comprise copper and the second substrate material 112 may comprise another material, such as tantalum nitride, tantalum, ruthenium, cobalt, manganese, and their alloys. Appearance of tantalum ions in the spectrum 132 can indicate that the copper first substrate material copper 110 has been removed, and the second substrate material 112 is now exposed to the pad 104. In other examples, the pad 104 can be monitored for any other suitable change in chemistry indicating a process endpoint. Some examples of techniques that can be implemented using the optical monitoring system 124 include ultraviolet (UV)-visible spectroscopy (absorbance or emission). It will also be appreciated that other suitable techniques, such as infrared spectroscopy, can also be used.

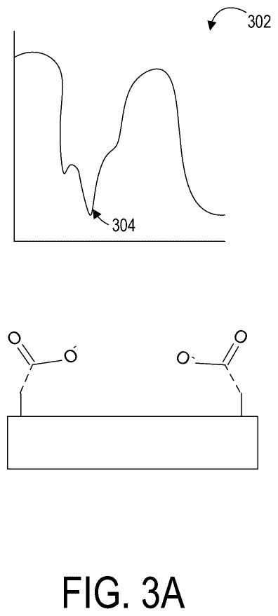

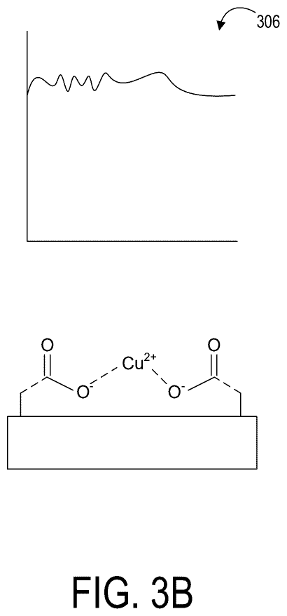

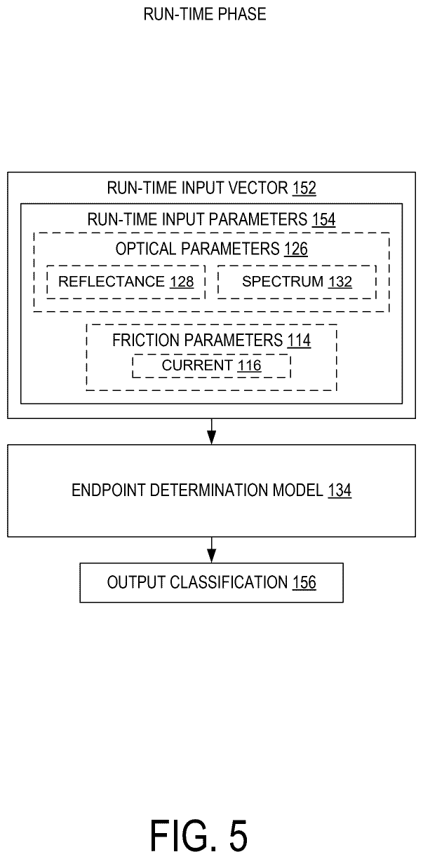

The monitored one or more parameters of the pad can additionally or alternatively be used to determine an endpoint of a pad use cycle. As described above, substrate materials, such as copper, can bind to functional groups of the pad 104. This can change the spectroscopic properties of the pad 104. For example, FIG. 3A shows a prophetic example of a Fourier-transform infrared (FTIR) spectrum 302 of a functionalized surface of a planarization pad. A peak at 304 indicates presence of an unbound functional group. Binding of substrate material (e.g., copper) to the planarization pad can cause the FTIR signature of the planarization pad to change. For example, FIG. 3B shows a prophetic example of an FTIR spectrum 306 of a saturated planarization pad. The peak 304 is not present in the spectrum 306 of FIG. 5B. This can occur because the planarization pad is saturated with substrate material, which can change vibrational characteristics of the functional groups and/or increase reflectance of the pad such that the infrared signature of the functional groups is changed or obscured. This indicates the endpoint of the pad use cycle.

The functionalization of the pad may be regenerated by performing a regeneration process to remove the portion of the substrate material bound to the pad. Additional aspects of regenerating the functionalization are described in more detail in U.S. patent application Ser. No. 17/729,805 entitled PAD SURFACE REGENERATION AND METAL RECOVERY, filed on Apr. 26, 2022, the entire contents of which are hereby incorporated by reference for all purposes. This can result in a clean pad suitable for reuse in another planarization process.

The monitored one or more parameters of the planarization pad can additionally or alternatively indicate an endpoint of the regeneration process. In some examples, regeneration includes dissociating chelates that are bonded to the pad during processing. As a result, the substrate material bonded to the pad is released. This can change the monitored one or more parameters of the pad in a manner that can be correlated to the regeneration of the pad. For example, the infrared signature of the pad may revert to the form illustrated in FIG. 3A. This can also enable the monitoring techniques described above to monitor the need for regeneration and to detect an endpoint of the regeneration process.

Referring again to FIG. 1, in some examples, the controller 120 is configured to use an endpoint determination model 134 to determine whether the endpoint is reached. The endpoint determination model 134 is trained to detect the endpoint of the planarization process (e.g., as a binary classification problem, as described in more detail below). It will also be appreciated that other models can additionally or alternatively be used to determine an endpoint of the pad use cycle (e.g., if the pad requires regeneration), and/or an endpoint of the regeneration process.

FIG. 4 shows the endpoint determination model 134 of FIG. 1 during a training phase. In the training phase, the endpoint determination model 134 is configured to receive, as input, a training input vector 136. The training input vector 136 comprises a plurality of training data pairs 138. Each training data pair 138 includes one or more training input parameters 140. In some examples, the one or more training input parameters 140 comprise one or more training optical parameters 148 and/or training friction parameters 150. As described in more detail below, the training optical parameters 148 correspond to the optical parameters 126 of FIG. 1 and the training friction parameters 150 correspond to the friction parameters 114 of FIG. 1. It will also be appreciated that the training input parameters 140 can additionally or alternatively include any other suitable parameters, such as other measurements of the pad and/or the substrate.

In some examples, the endpoint determination model 134 is trained on labeled data. In some such examples, each training data pair 138 further includes a ground-truth output label 142. For example, the ground-truth output label 142 can comprise a binary output classification that indicates whether an endpoint is met, as indicated at 144, or whether the endpoint is not met, as indicated at 146.

In the example of FIG. 4, the plurality of training data pairs 138 are used to train the endpoint determination model to predict a classified output based on run-time input parameters. The run-time implementation of the trained endpoint determination model 134 is illustrated in FIG. 5.

It will be appreciated that the particular set of features included in the training data pairs 138 during the training phase will be included for each and every training session and will also be included in the input vector in the run-time phase, with each parameter indicated on a normalized scale of zero to one. When a particular feature is present in one session or from one sensor, but is not present in another session or from another sensor, it will be indicated as zero when it is not present.

In some examples, the endpoint determination model 134 includes a neural network. The training may take place using any suitable method(s), such as by using backpropagation with gradient descent. As the neural network is trained, an input vector (e.g., a vector comprising a normalized form of the training input parameters 140) and matched ground truth labels 142, are applied to an input layer and an output layer respectively, and the weights in the network are computed through gradient descent and the backpropagation algorithm, for example, such that the trained neural network will properly classify (or properly value) the input vector to the matched ground truth classification or in the output layer. In other examples, another suitable model may be used, such as a neural network of another structure, a support vector machine, a decision tree, a random forest, a naïve Bayesian algorithm, etc.

In a run-time implementation, one example of which is depicted in FIG. 5, the endpoint determination model 134 is configured to receive, as input, a run-time input vector 152 comprising one or more run-time input parameters 154. In some examples, the run-time input parameters 154 include the optical parameters 126 and/or the friction parameters 114 of FIG. 1. The run-time input vector 152 is input into the trained endpoint determination model 134, to thereby cause the endpoint determination model 134 to output a predicted classification 156 of a status of the planarization process. The output classification corresponds to the labels used during the training phase. In this manner, the output classification 156 may indicate that the endpoint of the planarization process has been reached.

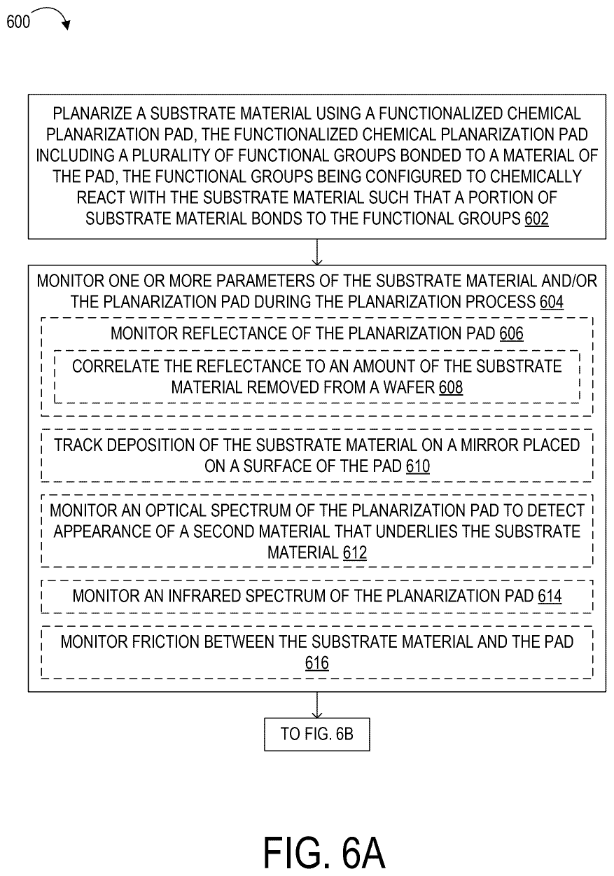

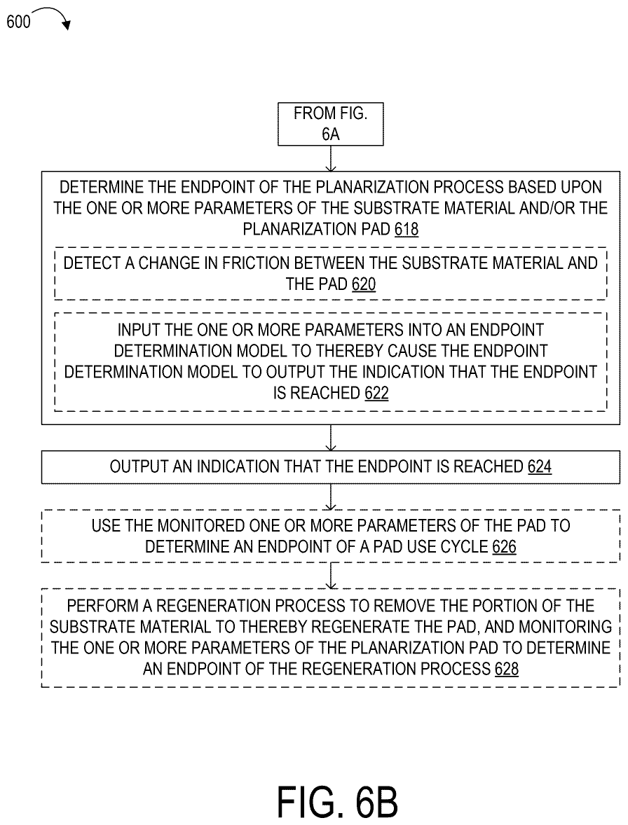

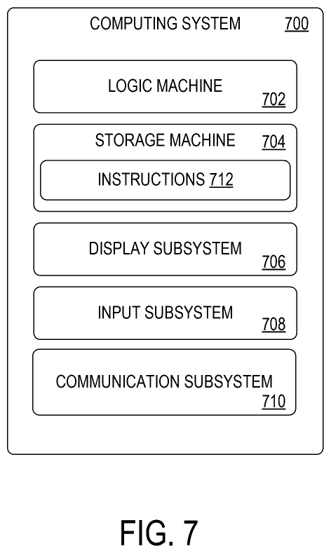

FIGS. 6A-6B show a flow diagram depicting an example method 600 for determining an endpoint of a planarization process. The following description of the method 600 is provided with reference to FIGS. 1-5 above and FIG. 7 below. It will be appreciated that the method 600 also can be performed in other contexts.

Referring first to FIG. 6A, at 602, the method 600 comprises planarizing a substrate material using a functionalized chemical planarization pad, the functionalized chemical planarization pad including a plurality of functional groups bonded to a material of the pad, the functional groups being configured to chemically react with the substrate material, with or without the assistance of reagents in a solution, such that a portion of substrate material bonds to the functional groups. For example, the pad 104 of FIG. 1 can be used to process the substrate 108.

The method 600 further comprises, at 604, monitoring one or more parameters of the substrate material and/or the planarization pad during the planarization process. In some examples, at 606, monitoring the one or more parameters comprises monitoring reflectance of the planarization pad. For example, the optical monitoring system 124 can be used to monitor the reflectance of the pad 104. At 608, in some examples, monitoring the reflectance of the planarization pad comprises correlating the reflectance to an amount of the substrate material removed from a wafer. In this manner, and as described above, the reflectance can be used to track the amount of the substrate material removed in real time, and to determine when the endpoint of the polishing process is reached.

In some examples, at 610, monitoring the one or more parameters comprises tracking deposition of the substrate material on a mirror placed on a surface of the pad. For example, the optical monitoring system 210 of FIG. 2 is configured to track deposition of a substrate material on a mirror 214 placed on a surface of the pad 204. For example, the optical monitoring system 210 can detect a change in reflectance of the mirror 214 during processing, which can be correlated to an amount of the substrate material removed from a wafer.

At 612, in some examples, monitoring the one or more parameters comprises monitoring an optical spectrum of the planarization pad to detect appearance of a second material that underlies the substrate material. For example, an optical spectrum 132 of the planarization pad 104 of FIG. 1 can be monitored to detect appearance of the second substrate material 112 underlying the first substrate material 110. Appearance of the second substrate material 112 in the spectrum 132 can indicate that the first substrate material 110 has been removed, and the second substrate material 112 is now exposed to the pad 104.

In some examples, at 614, monitoring the one or more parameters comprises monitoring an infrared spectrum of the planarization pad. For example, FIG. 3A shows a prophetic example of an FTIR spectrum 302 of a functionalized surface of a planarization pad. In contrast, FIG. 3B shows a prophetic example of an FTIR spectrum 306 of a saturated planarization pad. The differences between the FTIR spectra can indicate that the planarization pad is saturated and has reached an endpoint of its use cycle.

At 616, in some examples, monitoring the one or more parameters comprises monitoring friction between the substrate material and the pad. For example, the friction parameters 114 of FIG. 1, such as a drive current 116 for a substrate carrier motor 118, can be monitored during the planarization process. A change in the friction coefficient between the substrate 108 and the pad 104 will affect the drive current 116, which can be used to detect the process endpoint.

Referring now to FIG. 6B, at 618, the method 600 further comprises determining the endpoint of the planarization process based upon the one or more parameters of the substrate material and/or the planarization pad. In some examples, at 620, determining the endpoint of the planarization process comprises detecting a change in friction between the substrate material and the pad. For example, as described above, when the underlying film is reached, there can be a change in the value of the friction coefficient. This can indicate the endpoint of the process.

At 622, in some examples, determining the endpoint of the planarization process comprises inputting the one or more parameters into an endpoint determination model to thereby cause the endpoint determination model to output the indication that the endpoint is reached. For example, FIGS. 4-5 schematically illustrate an example of an endpoint determination model trained to detect the endpoint. Advantageously, the endpoint determination model can use a plurality of different input types to determine when the endpoint is met.

The method 600 further comprises, at 624, outputting an indication that the endpoint is reached. For example, the controller 120 of FIG. 1 is configured to output indication 122.

In some examples, the method 600 further comprises, at 624, using the monitored one or more parameters of the pad to determine an endpoint of a pad use cycle. For example, the optical parameters 126 and/or the friction parameters 114 of FIG. 1 can be monitored to detect the endpoint of the pad use cycle. In this manner, the controller 120 can determine when to replace the pad or initiate a pad regeneration process.

At 628, in some examples, the method 600 further comprises performing a regeneration process to remove the portion of the substrate material to thereby regenerate the pad, and monitoring the one or more parameters of the planarization pad to determine an endpoint of the regeneration process. In this manner, the monitoring techniques described above can be used to determine when a pad is capable of reuse.

FIG. 7 schematically shows a non-limiting example of a computing system 700 that can enact one or more of the methods and processes described above. Computing system 700 is shown in simplified form. Computing system 700 can take the form of one or more personal computers, workstations, computers integrated with substrate processing tools, and/or network accessible server computers.

Computing system 700 includes a logic machine 702 and a storage machine 704. Computing system 700 can optionally include a display subsystem 706, input subsystem 708, communication subsystem 710, and/or other components not shown in FIG. 7. Controller 120 is an example of computing system 700.

Logic machine 702 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 704 includes one or more physical devices configured to hold instructions 712 executable by the logic machine to implement the methods and processes described herein. When such methods and processes are implemented, the state of storage machine 704 can be transformed—e.g., to hold different data.

Storage machine 704 can include removable and/or built-in devices. Storage machine 704 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 704 can include volatile, nonvolatile, dynamic, static, read/write, read-only, random-access, sequential-access, location-addressable, file-addressable, and/or content-addressable devices.

It will be appreciated that storage machine 704 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 702 and storage machine 704 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 706 can be used to present a visual representation of data held by storage machine 704. This visual representation can take the form of a graphical user interface (GUI). As the herein described methods and processes change the data held by the storage machine, and thus transform the state of the storage machine, the state of display subsystem 706 can likewise be transformed to visually represent changes in the underlying data. Display subsystem 706 can include one or more display devices utilizing virtually any type of technology. Such display devices can be combined with logic machine 702 and/or storage machine 704 in a shared enclosure, or such display devices can be peripheral display devices.

When included, input subsystem 708 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 710 can be configured to communicatively couple computing system 700 with one or more other computing devices. Communication subsystem 710 can include wired and/or wireless communication devices compatible with one or more different communication protocols. As non-limiting examples, the communication subsystem can be configured for communication via a wireless telephone network, or a wired or wireless local- or wide-area network. In some examples, the communication subsystem can allow computing system 700 to send and/or receive messages to and/or from other devices via a network such as the Internet.

This disclosure is presented by way of example and with reference to the associated drawing figures. Components, process steps, and other elements that can be substantially the same in one or more of the figures are identified coordinately and are described with minimal repetition. It will be noted, however, that elements identified coordinately can also differ to some degree. It will be further noted that some figures can be schematic and not drawn to scale. The various drawing scales, aspect ratios, and numbers of components shown in the figures can be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein comprises A, B, or a combination of A and B. The terminology “one or more of A, B, or C” is equivalent to A, B, and/or C. As such, “one or more of A, B, or C” as used herein comprises A individually, B individually, C individually, a combination of A and B, a combination of A and C, a combination of B and C, or a combination of A, B and C.

It will be understood that the configurations and/or approaches described herein are example in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for determining an endpoint of a planarization process, the method comprising:
planarizing a substrate material using a functionalized chemical planarization pad, the functionalized chemical planarization pad including a plurality of functional groups bonded to a material of the pad, the functional groups, with or without the assistance of reagents in a solution, being configured to chemically react with the substrate material such that a portion of substrate material is removed at least in part by bonding to the functional groups;
monitoring one or more parameters of the substrate material and/or the planarization pad during the planarization process;
determining the endpoint of the planarization process based upon the one or more parameters of the substrate material and/or the planarization pad; and
outputting an indication that the endpoint is reached.

2. The method of claim 1, wherein monitoring the one or more parameters comprises monitoring reflectance of the planarization pad.

3. The method of claim 2, wherein monitoring the reflectance of the planarization pad comprises correlating the reflectance to an amount of the substrate material removed from a wafer.

4. The method of claim 1, wherein monitoring the one or more parameters comprises tracking deposition of the substrate material on a mirror placed on a surface of the pad.

5. The method of claim 1, wherein monitoring the one or more parameters comprises monitoring an optical spectrum of the planarization pad to detect appearance of a second material that underlies the substrate material.

6. The method of claim 1, wherein monitoring one or more parameters comprises monitoring an infrared spectrum of the planarization pad.

7. The method of claim 1, wherein monitoring the one or more parameters comprises monitoring friction between the substrate material and the pad.

8. The method of claim 7, wherein determining the endpoint of the planarization process comprises detecting a change in friction between the substrate material and the pad.

9. The method of claim 1, further comprising using the monitored one or more parameters of the pad to determine an endpoint of a pad use cycle.

10. The method of claim 1, further comprising performing a regeneration process to remove a portion or all of the substrate material bound to the pad to thereby regenerate the pad, and monitoring the one or more parameters of the planarization pad to determine an endpoint of the regeneration process.

11. The method of claim 1, wherein determining the endpoint of the planarization process comprises inputting the one or more parameters into an endpoint determination model to thereby cause the endpoint determination model to output the indication that the endpoint is reached.

12. A planarization tool, comprising:
a functionalized chemical planarization pad comprising a plurality of functional groups bonded to a material of the pad, the functional groups being configured to chemically react with a substrate material, with or without the assistance of reagents in a solution, such that a portion of substrate material bonds to the functional groups;
a substrate holding system configured to hold a substrate against the functionalized chemical planarization pad;
an optical monitoring system configured to monitor one or more optical parameters of the substrate material and/or the planarization pad during the planarization process; and
a computing system comprising one or more processors configured to determine the endpoint of the planarization process based upon the one or more optical parameters of the substrate material and/or the planarization pad, and output an indication that the endpoint is reached.

13. The planarization tool of claim 12, wherein the optical monitoring system is configured to monitor reflectance of the planarization pad.

14. The planarization tool of claim 12, wherein the optical monitoring system is configured to track deposition of the substrate material on a mirror placed on a surface of the pad.

15. The planarization tool of claim 12, wherein the optical monitoring system is configured to monitor an optical spectrum of the planarization pad to detect appearance of a second material that underlies the substrate material.

16. The planarization tool of claim 12, wherein the optical monitoring system is configured to monitor an infrared spectrum of the planarization pad.

17. The planarization tool of claim 12, wherein the one or more processors are further configured to use the monitored one or more optical parameters of the pad to determine an endpoint of a pad use cycle.

18. The planarization tool of claim 12, wherein the one or more processors are further configured to monitor the one or more optical parameters of the planarization pad to determine an endpoint of a pad regeneration process.

19. The planarization tool of claim 12, wherein the one or more processors are further configured to input the one or more monitored optical parameters into an endpoint determination model to thereby cause the endpoint determination model to output the indication that the endpoint is reached.

20. A planarization tool, comprising:
a functionalized chemical planarization pad comprising a plurality of functional groups bonded to a material of the pad, the functional groups being configured to chemically react with a substrate material such that a portion of substrate material bonds to the functional groups;
a substrate holding system configured to hold a substrate against the functionalized chemical planarization pad;
a friction monitoring system configured to monitor friction between the substrate material and the pad; and
a computing system comprising one or more processors configured to,
determine the endpoint of the planarization process based upon detecting a change in friction between the substrate material and the pad, and
output an indication that the endpoint is reached.
